(19) United States
(12) Patent Application Publication
(10) Pub. No.: US 2025/0220936 A1
(43) Pub. Date: Jul. 3, 2025

(54) INTEGRATED CIRCUIT (IC) WITH DOPANT PROFILE CONTROL IN A HETEROJUNCTION BIPOLAR TRANSISTOR (HBT)

(71) Applicant: TEXAS INSTRUMENTS INCORPORATED, Dallas, TX (US)

(72) Inventors: Tatsuya Tominari, Plano, TX (US); Jerald Rock, Lisbon, ME (US); Nicholas Gilmour Brundage, Waterboro, ME (US)

(21) Appl. No.: 18/396,832

(22) Filed: Dec. 27, 2023

(51) Int. Cl. H01L 29/737; H01L 21/02; H01L 27/082; H01L 29/66

(52) U.S. Cl. CPC H10D 10/80; H01L 21/02211; H10D 10/021; H10D 84/645

(57) ABSTRACT

An integrated circuit (IC) device includes a semiconductor substrate and a heterojunction bipolar transistor comprising a collector region, a base region and an emitter region, the collector region formed in or over the semiconductor substrate, the base region disposed between the collector region and the emitter region, the base region comprising a heteroepitaxial portion including a narrow band of an n-dopant region.

### FIELD OF THE DISCLOSURE

Disclosed implementations relate generally to the field of integrated circuits (ICs) and IC fabrication. More particularly, but not exclusively, the disclosed implementations relate to an IC device including a heterojunction bipolar transistor (HBT) having dopant profile control.

### BACKGROUND

Epitaxy is used in semiconductor fabrication to create a suitable crystalline foundation layer on which to build a semiconductor device, to deposit a crystalline film with engineered electrical properties, and/or to alter mechanical attributes of an underlayer in a way that improves its electrical conductivity. In some instances, an epitaxial layer can be doped during deposition by adding impurities to the source gas in order to obtain desired electrical properties of the epitaxial layer.

A heterojunction bipolar transistor (HBT) is generally a bipolar junction transistor (BJT) that implements different semiconductor materials for the different regions of the transistor, e.g., the emitter region, the base region, and/or the collector region. For example, the emitter region having a semiconductor material different from the epitaxially grown material of the base region creates a heterojunction in the HBT. An HBT can have a high operating frequency and, therefore, may be implemented in high frequency circuits, such as radio frequency (RF) applications.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a method of fabricating an IC device is disclosed. The method may comprise, among others, forming a first portion of a base region over a collector region of a heterojunction bipolar transistor (HBT), the first portion formed epitaxially at a first temperature; forming a second portion of the base region over the first portion, the second portion formed epitaxially at a lower second temperature; and forming a third portion of the base region over the second portion, the third portion formed epitaxially at the first temperature. In some arrangements, the first and third portions may be formed using a first type of silicon precursor, whereas the second portion may be formed using a different second type of silicon precursor. In some arrangements, the first type of silicon precursor comprises dichlorosilane (DCS, SiCl₂H₂) and the second type of silicon precursor comprises silane (SiH₄). In some arrangements, an example method may further comprise applying hydrogen chloride (HCl) as an etchant at a first flow rate while forming the second portion of the HBT and at one or more second flow rates higher than the first flow rate while forming the first and third portions of the HBT.

In one example, a method of fabricating an IC device is closed. The method may comprise, among others, forming a first portion of a base region over a collector region of an HBT, the second portion formed epitaxially using a first type of silicon precursor (e.g., DCS); forming a second portion of the base region over the first portion, the second portion formed epitaxially using a different second type of silicon precursor (e.g., silane); and forming a third portion of the base region over the second portion, the third portion formed epitaxially using the first type of silicon precursor. In some arrangements, the first and third portions are formed at a first temperature and the second portion is formed at a lower second temperature.

In one example, an IC device is disclosed, which may comprise, among others, a semiconductor substrate; and an HBT comprising a collector region, a base region and an emitter region, the collector region formed in or over the semiconductor substrate, the base region disposed between the collector region and the emitter region, the base region comprising a heteroepitaxial portion including a narrow band of an n-dopant region, where the narrow band may be of about one-tenth thickness of the heteroepitaxial portion. In some arrangements, the heteroepitaxial portion may comprise silicon-germanium (SiGe) material and the n-dopant region may be doped with phosphorus at a peak concentration range of about 5×10¹⁸ atoms/cm³ to 5×10¹⁹ atoms/cm³. In some arrangements, the narrow band of the n-dopant region may overlap a trough of a germanium distribution profile in the heteroepitaxial portion and may have a thickness of about 5 nm. In some arrangements, the IC device may be or include a fully self-aligned (FSA) selective base PNP HBT device.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIG. 1 depicts a cross-sectional view of an IC device according to some examples;

FIG. 2 depicts a cross-sectional view of an IC device according to some examples;

FIG. 3 depicts a cross-sectional view of a layered structure of a base region of an HBT according to some examples;

FIGS. 4A and 4B depict flowcharts of methods of IC fabrication according to some examples;

FIG. 5 depicts a table of processing conditions for fabricating a layered base region as part of an HBT according to some examples;

FIG. 6 is a chart depicting base target concentration gradients of germanium, phosphorus and carbon in different growth phases for fabricating the layered structure of FIG. 3 using the processing conditions of FIG. 5 according to some examples; and

FIG. 7 is a chart depicting dopant profiles in an HBT according to some examples.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of an IC device including one or more heterojunction bipolar transistors (HBTs) and techniques for controlling dopant profiles in a base region of an HBT will be set forth below in the context of a P-N-P HBT having an epitaxially grown layered base region that may be doped with Group V dopants, e.g., phosphorus.

Some examples of the present disclosure generally relate to providing dopant profile control in an HBT where a base region may comprise a compound semiconductor material. Methods of semiconductor processing to fabricate an IC device including an HBT as well as a semiconductor device structure for implementing an HBT with a multilayered base region are described. Various examples described herein may implement a specific semiconductor material system and specific dopants. For example, some arrangements implement a p-doped silicon (Si) emitter region and an n-doped silicon-germanium (SiGe) base region having a plurality of sub-layers, and a p-doped Si collector region, hereinafter collectively referred to as a “Si/SiGe system” for simplicity, where the n-type dopants may comprise phosphorus (P) or arsenic (As) to achieve a heterojunction in the base region and the p-type dopants may comprise boron. Whereas dopant profile control in p-n-p HBTs is set forth herein, some aspects of the present disclosure may apply more generally to different material systems and different dopants in the implementation of HBTs comprising a combination of elements selected from Group III, Group IV and/or Group V.

Si/SiGe systems for HBTs have been observed to have a high operating speed. A higher concentration of germanium in the SiGe base region can result in a higher current gain, and a steep germanium concentration profile can achieve a strong drift field to boost device speed. Further, phosphorus doping with a high concentration in the SiGe base region may have a narrow width in order to avoid punch-through.

Processing to implement a Si/SiGe system doped with phosphorus for an HBT has been observed to have various challenges related to the phosphorus concentration profile. For example, segregation diffusion of phosphorus can cause phosphorus to diffuse from an SiGe layer that has a higher germanium concentration to an interface between (i) that silicon germanium layer and (ii) a silicon layer or another SiGe layer (or sub-layer) that has a lower germanium concentration. Segregation diffusion of phosphorus can occur during processing at any temperature, even at a low temperature. Segregation diffusion of phosphorus may be particularly exacerbated after processing at temperatures greater than 650° C., such as in a range from about 650° C. to about 800° C.

Further, surface segregation of phosphorus has been observed to occur during epitaxial growth of an SiGe layer (or a sub-layer in a multilayered architecture) that is in-situ doped with phosphorus during the epitaxial growth. Surface segregation during epitaxial growth of the SiGe layer can result in accumulation of phosphorus on a top or upper surface of the SiGe layer/sub-layer.

Additionally, phosphorus has been observed to have a relatively high diffusion mobility in silicon-germanium material used in an HBT. Particularly, phosphorus may diffuse relatively rapidly during periods of high thermal stress, which can occur during processing after deposition of the SiGe layer that is doped with phosphorus, depending on the process flows and/or device integration of a technology node. As an example, in complementary-bipolar and complementary-metal-oxide-semiconductor (CBiCMOS) applications, the SiGe layer doped with phosphorus may be subjected to an anneal, such as a rapid thermal anneal (RTA), that is implemented to activate dopants in CMOS components. Accordingly, an HBT can incur a number of thermal stresses after the formation of the base of the HBT due to co-integration of other devices in a CBiCMOS design.

Any of these challenges, individually and/or in combination can have a deleterious effect on the performance of an HBT. For example, the distribution profile of phosphorus in the SiGe base region may be altered such that a peak concentration of phosphorus may be disposed outside of the SiGe material, which can result in a PN junction being located outside of the SiGe region. Accordingly, the benefits of an intended heterojunction may not be realized by the HBT having such an altered dopant profile.

Various aspects described herein address these challenges. Any aspect may be implemented individually or in combination with others to address one or more of the above challenges. Other challenges may be addressed in respect of applications involving different Group V dopants (e.g., As) and/or other compound semiconductor material systems by implementing aspects described herein. According to some examples, a layered structure is deposited to form a base region of an HBT where at least some of the sub-layers may be epitaxially grown in a sequential manner (e.g., an N^{th} sub-layer may be epitaxially grown on or over an (N−1)^{th} sub-layer, and so on, where the N^{th} sub-layer may or may not be in-situ doped with a suitable dopant species). Further, an epitaxial sub-layer may be heteroepitaxial with respect to an adjacent sub-layer in the sense that the epitaxial sub-layer may comprise a different material or composition, or a polytype (e.g., in terms of constituent semiconductor materials, different dopant ratios, concentrations, etc.). Additionally and/or alternatively, there may be a lack of clear demarcation between the sub-layers in some examples because of diffusion of species in the layered structure of a base region.

In some arrangements, an example HBT's base region may comprise a plurality of sub-layers, also referred to as “layers”, “portions”, or “sub-portions”, or in terms of similar import depending on the context, where a layer may comprise a suitable compound semiconductor material (e.g., SiGe material) and a first sub-layer may be formed over a collector region of the HBT. A silicon cap layer may overlie the sub-layers of an HBT. Accordingly, depending on the context, an example HBT's base region may be visualized as having six layers/sub-layers in total (including the cap layer/sub-layer) or as a five-layer/sub-layer heteroepitaxial portion underlying a cap layer/sub-layer comprised of monocrystalline silicon. To address segregation diffusion of phosphorus, an example of the present disclosure may include epitaxially growing a portion of three sub-layers based on processing conditions to achieve a concentration profile of a semiconductor species, e.g., germanium, such that the percentage concentration of the species is less in the middle sub-layer of the portion than in the two sub-layers of the portion adjacent to or immediately surrounding the middle sub-layer. Further, the middle sub-layer of the portion may be in-situ doped with a dopant, e.g., phosphorus, during epitaxial growth of the middle sub-layer, whereas the two surrounding sub-layers may not be in-situ doped with the dopant during each surrounding sub-layer's respective epitaxial growth. As the concentration of the semiconductor species (e.g., percentage concentration) in the two sub-layers is greater than the concentration of the semiconductor species of the middle sub-layer of the portion, the profile of the semiconductor species in the three sub-layer portion may roughly resemble what may be referred to as a two-humped camelback. Accordingly, in some examples of the present disclosure, the base region of an HBT may have a germanium profile that may comprise at least a portion colloquially referred to as a camelback profile.

In the above-described HBT examples, implementing the concentration of germanium in such a layered structure can cause the dopant (e.g., phosphorus) to be disposed in a sub-layer having a lower germanium concentration where that sub-layer interfaces with sub-layers having higher germanium concentrations. It is expected that such interfacial boundaries between differential concentrations may assist to confine the dopant within a sub-layer and therefore reduce segregation diffusion outside of a heteroepitaxial portion of the base region.

To address surface segregation, an example of the present disclosure may include epitaxially growing the sub-layer that is in-situ doped with the dopant and the sub-layer immediately over the in-situ doped sub-layer at a temperature regime lower than the temperature regimes that may be implemented for the epitaxial growth of sub-layers surrounding these two sub-layers. It is expected that reducing the temperature of the epitaxial growth can reduce occurrence of surface segregation. Furthermore, to accommodate lower temperature epitaxial processing for the two sub-layers, the silicon precursor mix used for the two sub-layers may also be modulated without negatively affecting the overall growth of the layered structure of a base region. As will be seen in detail below, example implementations may involve using a first type of silicon precursor that supports higher growth rates but requires higher temperatures for certain portions of the layered base region whereas a second type of silicon precursor that allows lower temperature processing may be used the growth of in-situ doped sub-layer and the sub-layer directly overlies the in-situ doped sub-layer. In further arrangements, various etchants and/or co-etchants used in the epitaxial growth processes, e.g., including but not limited to selective epitaxial growth (SEG) processes (also referred to as selective area epitaxy or SAE), may also be modulated according to some examples. In scenarios where a silicon precursor is also operable as an etchant, the flow rates of a co-etchant may therefore be modulated if that silicon precursor is replaced with another silicon precursor that does not have etching properties in a growth phase.

With respect to the issue of high diffusion mobility, some examples herein may include doping one or more sub-layers of the base region with another Group IV species, such as carbon, e.g., by in-situ doping using suitable precursors. It is expected that the presence of carbon can reduce diffusion of another dopant, e.g., a Group V species, such as phosphorus, within the heteroepitaxial portion of the base region.

Any of the foregoing aspects individually or together with one or more other aspects may be implemented according to the examples of the present disclosure, which may be configured to achieve a concentration profile of the n-type dopant having a peak concentration within a narrow region of the resulting heteroepitaxial portion or layer, thereby assist in realizing the putative benefits of the heterojunctional construction of an HBT. Additionally, with respect to Si/SiGe systems, a higher concentration of germanium may be achieved in a SiGe base sub-layer such that the HBT can have increased operating speed. As noted above, the above-described aspects may be implemented in any material system involving a variety of compound semiconductor materials and/or any dopants where applicable, without limitation.

As will be set forth in further detail below, different sub-layers of an HBT's base region may be processed using specific processing conditions that may be modulated depending on implementation so as to address one or more of the challenges set forth above. Further, the processing conditions set forth herein may be optimized such that example solutions herein may be advantageously configured to address the above challenges without negatively impacting the throughput as do some baseline techniques. In particular, some aspects of example solutions may involve modulating certain process conditions in order to reduce overall time periods required to grow an HBT's base region having suitable dopant profiles while avoiding the challenges noted herein. Whereas such examples and variations thereof may be expected to improve the throughput of HBT-based IC devices in a foundry without significantly adding to the costs, in addition to potentially reducing defects that could otherwise reduce yields, reliability or electrical performance of a product, no particular result is a requirement of the present disclosure unless explicitly recited in a particular claim.

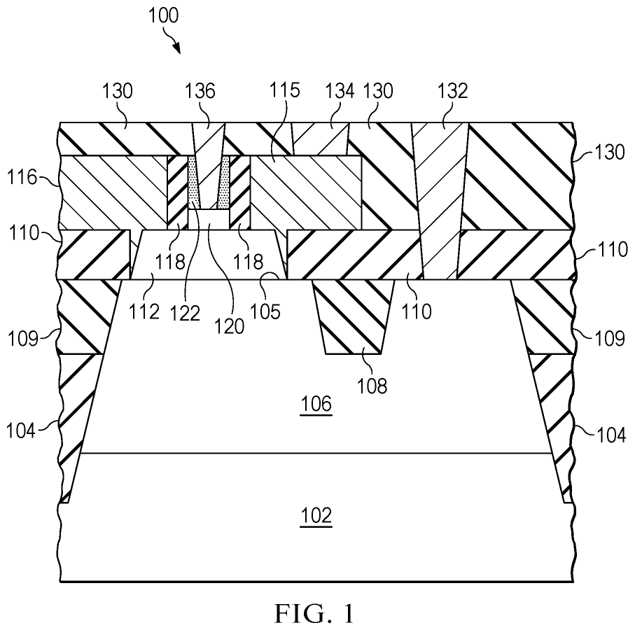

Turning to the drawing Figures, FIG. 1 depicts a cross-sectional view of an IC device 100 according to some examples. The IC 100 device, in this example, is a semiconductor device that is or includes a bipolar transistor, such as an HBT, whose structure is shown generically so as to not obscure aspects described herein. In particular, a number of different dielectric layers or structures may be illustrated and described as a single layer or structure in some instances. It is noted that, in such instances, multiple different dielectric layers or structures are contemplated within some examples. Additionally, intermediary or sacrificial mask layers that may be used in selective epitaxy processes (e.g., SEG/SAE), while not specifically shown in Figures, are contemplated within some examples described herein.

The IC device 100 includes a semiconductor substrate 102, which can be a bulk semiconductor material, a semiconductor-on-insulator (SOI), or any other appropriate semiconductor substrate. Depending on application, the semiconductor material of the semiconductor substrate 102 can be or include silicon (Si), silicon germanium (SiGe), the like, or a combination thereof. In some examples, the semiconductor substrate 102 is a silicon substrate, which may be singulated from a bulk silicon wafer at the conclusion of semiconductor processing.

Isolation regions 104 may be formed in the semiconductor substrate 102, and each isolation region 104 may extend at least from a top portion of the semiconductor substrate 102 (e.g., on and/or in which devices are formed) to some depth in the semiconductor substrate 102. The isolation regions 104 may be formed by a variety of isolation techniques such as shallow trench isolation (STI), deep trench isolation (DTI), local oxidation of semiconductor (LOCOS), or the like. Depending on implementation, the isolation regions 104 may include a suitable dielectric material, such as an oxide, a nitride, the like, or a combination thereof. In some arrangements, isolation regions 104 may include polysilicon-filled trenches surrounded by dielectric material. In general, one or more isolation regions 104 may be provided to define an active area on the semiconductor substrate 102 on, over, and/or in which a semiconductor device is to be formed.

A collector region 106 may be formed on the active area of the semiconductor substrate 102. In the illustrated example, the collector region 106 is a semiconductor material epitaxially grown on or over the active area of the semiconductor substrate 102. In other examples, the collector region 106 may be disposed wholly in the semiconductor substrate 102 (e.g., without an epitaxially grown material forming a part of the collector region 106) or at least partially in the semiconductor substrate 102. In some arrangements, a heavily doped buried layer (e.g., a p-type buried layer or PBL, not shown in this Figure) may be provided as part of the collector region 106. The semiconductor material of the collector region 106 may comprise monocrystalline material and may include Si, SiGe, and the like, or a combination thereof. In some examples, the collector region 106 may include silicon epitaxially grown by SEG on the active area of the semiconductor substrate 102 using any suitable epitaxial techniques, e.g., metalorganic vapor-phase epitaxy (MOVPE), liquid phase epitaxy (LPE), vapor phase epitaxy (VPE), molecular beam epitaxy (MBE), chemical beam epitaxy (CBE) and atomic layer epitaxy (ALE), etc., and may be suitably doped (e.g., p-type dopants such as boron in a p-n-p HBT design).

Depending in implementation, epitaxial processes set forth herein may involve a variety of complex interactions of different materials, often extant in multiple phases, e.g., gas, liquid, and/or solid phases, that may take place in a specialized chamber for growing epitaxial layers, one layer at a time (e.g., a single layer of atoms or molecules, referred to as a monolayer), over the substrate. Epitaxial growth may result in facets being formed as sidewall surfaces of the epitaxially grown material. The formation of facets may depend on the epitaxial growth conditions and the orientation of the crystalline surface on which the epitaxially grown material is grown. In broad terms, an epitaxial process may include the following steps and/or phenomena: transport of reactants to the substrate in a reaction chamber, transfer of reactants to substrate surface, adsorption of reactants on substrate, surface processes such as reaction and kinetics, desorption of products and/or byproducts, transfer of products/byproducts to main transport medium (e.g., gas), and exhausting/removal of gases and other byproducts away from the reaction chamber.

As illustrated in FIG. 1, isolation regions 108, 109 may be provided in the IC device 100 for facilitating lateral definition and/or formation of suitable contacting surfaces with respect to the collector region 106. In some arrangements, the isolation region 108 may extend from a top surface 105 of the collector region 106 to some depth in the collector region 106. The isolation regions 109 may be formed to laterally define the collector region 106 and may be disposed over the isolation regions 104 in the semiconductor substrate 102. Depending on implementation, the isolation regions 108, 109 can be an STI, DTI, or the like. The isolation regions 108, 109 may each include a dielectric material, such as an oxide, a nitride, the like, or a combination thereof.

A first dielectric layer 110 may be formed over the isolation regions 108, 109 and the collector region 106. As noted above, the first dielectric layer 110 may include multiple dielectric layers, such as an etch stop layer (e.g., comprising silicon nitride (SiN) or the like) and an inter-layer dielectric (e.g., comprising silicon dioxide (SiO₂) or the like) disposed on the etch stop layer (not specifically shown in FIG. 1). The first dielectric layer 110 may be deposited by any appropriate deposition process, which may be subsequently planarized by using a planarization process, such as chemical-mechanical polishing (CMP).

With respect to forming the remaining portions of an HBT, e.g., a base region and an emitter region that overlie the collector region 106, as well as with respect to forming an external region for providing connectivity to the base region in some implementations, a conductive layer 116 may be first deposited over the first dielectric layer 110. The conductive layer 116 may be formed by any appropriate deposition process, and may comprise a doped semiconductor material, e.g., n-doped material in a p-n-p HBT, which may be doped polysilicon, doped amorphous silicon, or non-doped poly/amorphous silicon followed by an n-type ion implant. An opening, also referred to an “emitter window” may be created through the conductive layer 116 and the first dielectric region 110 by using appropriate photolithography and etching processes, using a patterned SiO₂/SiN layer as a mask (not shown in this Figure), where the opening is configured to facilitate the formation of a base region 112 over the collector region 106. Concurrently, the patterning of the conductive layer 116 may also be configured to form one or more extrinsic regions 115 configured to provide electrical connectivity to the base region 112 to be formed over the collector region 106. A subsequent etching process may be configured to remove the SiO₂ layer while maintaining the patterned SiN layer for facilitating the formation of a base region, e.g., the base region 112, in the emitter window opening using SEG/SAE. As noted previously, the base region 112 may comprise a multilayered structure (not specifically shown in this Figure) where the semiconductor material of each sub-layer may comprise Si, SiGe, and the like, or a combination thereof. As will be set forth in detail further below, the different layers/sub-layers of the base region 112 may be formed in the opening in a sequential manner using suitable epitaxial processes (e.g., SEG/SAE) and process recipes configured to minimize the dispersion of dopant concentration without negatively impacting the processing time.

Dielectric spacers 118 may be disposed along the sidewalls of the opening through the extrinsic region 115, where the dielectric spacers 118 may extend to the base region 112. The dielectric spacers 118 can be formed by conformally depositing one or more dielectric layers in the opening and etching (e.g., anisotropically etching) the one or more dielectric layers such that the dielectric spacers 118 remain along the sidewalls of the opening while a portion of the base region 112 remain exposed over which an emitter region 120 may be formed subsequently. Similar to the dielectric layers described previously, the dielectric spacers 118 formed in the opening may comprise any appropriate dielectric material, such as SiN, SiO₂, and/or a combination thereof, or the like.

A suitably doped material (e.g., p-doped material) may form the emitter region 120 disposed in the opening defined by the spacers 118 and over the exposed base region 112. In the illustrated example, the emitter region 120 is a semiconductor material epitaxially grown on the base region 112 after forming the various sub-layers thereof in successive stages, which may include forming a silicon cap layer. The semiconductor material of the emitter region 120 is crystalline (e.g., monocrystalline) and may comprise Si, SiGe, and/or a combination thereof, or the like, that may be grown epitaxially (e.g., SEG/SAE).

A fill material 122 may be disposed on the emitter region 120, which may fill the opening initially and then patterned to form an orifice configured to facilitate contact formation in subsequent stages. In some arrangements, the fill material 122 may comprise a conductive material (such as a doped semiconductor material, e.g., doped polysilicon or doped amorphous silicon) or a dielectric material. The fill material 122 may be deposited using any appropriate deposition process. In some arrangements, the fill material 122 comprising polysilicon and the emitter region 120 comprising monosilicon may be deposited together at a same time.

A second dielectric layer 130 may be disposed over the patterned conductive layer 116 including the extrinsic region(s) 115, dielectric spacers 118, fill material 122, and the first dielectric layer 110. In some arrangements, the second dielectric layer 130 may comprise multiple dielectric layers/sub-layers and may operate as a pre-metal dielectric (PMD) layer, which may be formed by using any appropriate process and polished subsequently (e.g., by CMP). Suitable contact vias may be formed through the first and second dielectric layers 110 and 130 using photolithography and etching processes in order to provide openings to the collector region 106, the extrinsic region 115, and the emitter region 120, which may be silicided appropriately or overlaid by a metal silicide layer (e.g., cobalt silicide (CoSi))), not specifically shown in FIG. 1, prior to contact formation. As illustrated, a collector contact 132 is disposed through the second dielectric layer 130 and the first dielectric layer 110 and contacts the silicided surface of the collector region 106. Likewise, a base contact 134 is disposed through the second dielectric layer 130 and contacts the silicided extrinsic region 115 which is in electrical contact with the base region 112. An emitter contact 136 is disposed through the second dielectric layer 130 and contacts the silicided surface of the emitter region 120 and/or the fill material 122. In some arrangements where the fill material 122 is conductive, the emitter contact 136 may contact the fill material 122 without contacting the emitter region 120 and may be electrically connected to the emitter region 120. In the examples herein, contacts 132, 134, 136 may include one or more barrier and/or adhesion layers (e.g., titanium nitride (TiN), tantalum nitride (TaN), and the like, or a combination thereof) formed conformally in the contact via openings, which may be filled with a conductive fill material (e.g., a metal, such as tungsten (W), copper (Cu), a combination thereof, or the like).

As noted above, in some examples, the IC device 100 is or includes a bipolar transistor, and more particularly, a HBT, which may be a standalone device or integrated with other microelectronic circuits depending on the level of integration. Without limitation as to any particular technology node or product implementation, the description below sets forth various processes and materials for forming the multilayered structure of the base region 112 shown in FIG. 1. Further, whereas the examples below relate to a p-n-p HBT structure, an n-p-n HBT structure may also be implemented using aspects described herein in other examples, with suitable modifications applied mutatis mutandis.

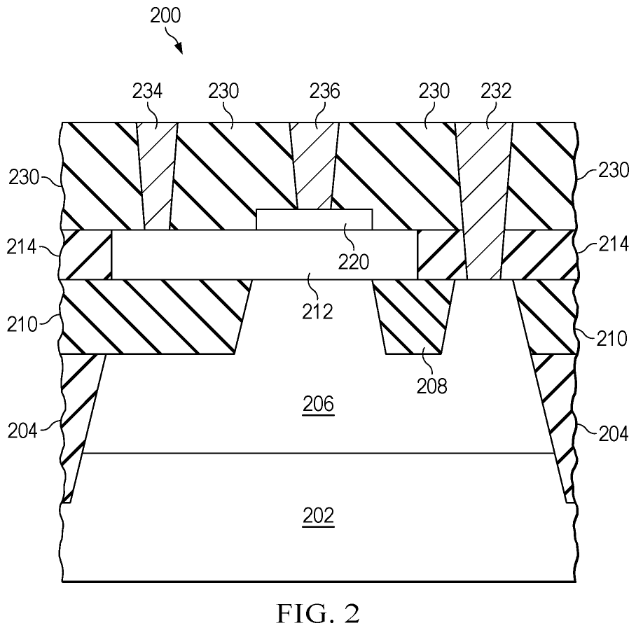

FIG. 2 depicts a cross-sectional view of an IC device 200 according to some examples where another arrangement of an HBT is illustrated. Similar to FIG. 1, the IC device 200 is shown generically so as to not obscure aspects described herein. As before, a semiconductor substrate 202, comprised of suitable material, may include various isolation regions 204, such as DTIs, STIs, or the like, which may be configured to define an active area on the semiconductor substrate 202 on, over, and/or in which a semiconductor device is to be formed. A collector region 206 is disposed on or over the active area of the semiconductor substrate 202. A multilayered base region 212 is disposed between the collector region 206 and an emitter region 220, where the base region 212 may be formed in a nonselective epitaxial SiGe process. Unlike the example shown in FIG. 1, the IC device 200 of FIG. 2 does not include an external region for providing connectivity with respect to the base region 212. Instead, the base region 212 is formed so as to support a contact 234 directly. Whereas there is no external region overlying the base region 212, a window or opening may be formed through a dielectric layer 214 overlying the collector region 206 to facilitate the formation of the base region 212 over the collector region 206 using SEG/SAE processing similar to the formation of the base region 112 shown in FIG. 1. The emitter region 220, formed on or over the base region 212 after the formation of the base region 212, may have a contact 236 thereto without an opening that is lined with dielectric sidewalls and/or filled with conductive fill material as is the case in the example of FIG. 1. The collector region 206, defined by isolation regions 208, 210, may be contacted with a contact 232 formed through one or more dielectric layers 214, 230, which are formed similar to the dielectric layer arrangement 110, 130 shown in FIG. 1. Further, the isolation regions 210 may be formed over isolation regions 204 that are analogous to the isolation regions 104 of the IC device 100 in FIG. 1. Apart from the distinctions set forth above, the IC device 200 is substantially similar to the IC device 100 of FIG. 1 and the various layers/sub-layers of a multilayered structure forming the base region 212 may be fabricated using similar process conditions used in fabricating the base region 112 according to the examples herein.

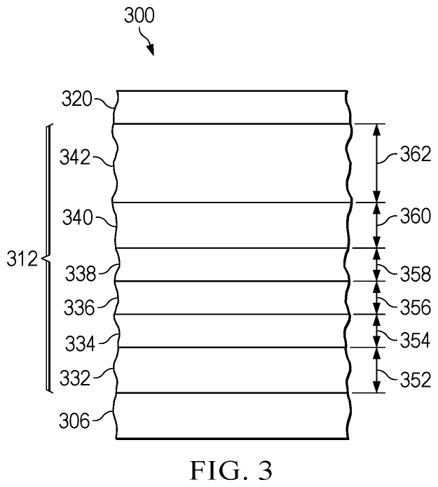

FIG. 3 illustrates a vertical architecture of a representative HBT 300, where a cross-sectional view of a multilayered structure of a base region 312 is shown according to some examples. In one arrangement, a first base sub-layer 332 of the base region 312 is disposed on or over a collector region 306 of the representative HBT 300. A second base sub-layer 334 of the base region 312 is disposed on or over the first base sub-layer 332 in a vertical stack formation. In similar fashion, a third base sub-layer 336 of the base region 312 is disposed on or over the second base sub-layer 334. A fourth base sub-layer 338 of the base region 312 is disposed on or over the third base sub-layer 336. A fifth base sub-layer 340 of the base region 312 is disposed on or over the fourth base sub-layer 338. A cap sub-layer 342 of the base region 312 is disposed on or over the fifth base sub-layer 340. An emitter region 320 is disposed on or over the cap sub-layer 342. As will be seen below, each of the base sub-layers 332-340 and the cap layer 342 (which may be deemed a sixth sub-layer of the base region 312 in some examples), may be deposited, grown, or otherwise formed, in respective phases of a process flow having a corresponding set of process conditions each that may be adapted, modulated, adjusted and/or otherwise optimized to help achieve a narrow dopant distribution profile in the base region 312 while minimizing the amount of time required to fabricate the base region 312 having a given overall thickness.

The collector region 306, the base region 312, and the emitter region 320 of FIG. 3 can be visualized as being analogous to the collector region 106, the base region 112, and the emitter region 120, respectively, of the IC device 100 depicted in FIG. 1, according to some examples. In similar fashion, the collector region 306, the base region 312, and the emitter region 320 of FIG. 3 may be analogous to the collector region 206, the base region 212, and the emitter region 220, respectively, of the IC device 200 depicted in FIG. 2, according to some examples.

Depending on application and processing conditions, the various sub-layers of the base region 312 may each have a respective thickness in a direction along a surface normal with respect to a major surface of an IC device containing the representative HBT 300, e.g., a top surface of the semiconductor substrate (not specifically shown in this Figure). Where the thicknesses are measured along a direction extending inward (e.g., towards the collector region 306) from a bottom surface of the emitter region 320, the thicknesses of the base sub-layers may be seen as corresponding depths of the respective base sub-layers, with the bottom surface of the emitter region 320 being a reference point of zero depth. Accordingly, the cap layer/sub-layer 342 may be viewed as the top-most layer/sub-layer of the base region 312, e.g., closest to the emitter region 320, whereas the first base sub-layer 332 may be viewed as the deepest or bottom-most layer/sub-layer of the base region 312, e.g., closest to the collector region 306.

By way of illustration, the first base sub-layer 332 has a first thickness 352; the second base sub-layer 334 has a second thickness 354; the third base sub-layer 336 has a third thickness 356; the fourth base sub-layer 338 has a fourth thickness 358; the fifth base sub-layer 340 has a fifth thickness 360; and the cap sub-layer (or the sixth base sub-layer) 342 has a sixth thickness 362. Depending on application, each of the various base sub-layers may have a corresponding thickness ranging from about a few nanometers (nm) to about a few tens of nanometers.

In some examples, the thicknesses of some of the base sub-layers may be approximately equal. In some examples, the thicknesses 352, 356, 358 of the first, third, and fourth base sub-layers 332, 336, 338 can be in a range from about 2 nm to about 10 nm. In some examples, the thicknesses 354, 360 of the second and fifth base sub-layers 334, 340 can be in a range from about 5 nm to about 40 nm. In some examples, the thickness 362 of the cap sub-layer 342 can be in a range from about 10 nm to about 50 nm. Although various thicknesses and relations between thicknesses of layers have been given as examples, any appropriate thickness can be implemented for a given sub-layer.

The base sub-layers 332, 334, 336, 338, 340 and the cap sub-layer 342 are each comprised of an appropriate semiconductor material having a crystalline structure (e.g., monocrystalline). The base sub-layers 332, 334, 336, 338, 340 may also be doped with appropriate dopants. The base sub-layers 332, 334, 336, 338, 340 are formed (e.g., epitaxially grown) with at least one semiconductor species that is different from or generally not included in the collector region 306, the cap sub-layer 342, and/or the emitter region 320. The inclusion of at least one different semiconductor species in varying compositions and/or concentrations may result in the formation of a heteroepitaxial layer or portion of the base region 312, which in turn may form a heterojunction, e.g., with respect to the cap sub-layer 342 and/or the emitter region 320, as part of the representative HBT 300. In the examples that are described in the context of Si/SiGe systems, the at least one different semiconductor species comprises germanium. Examples below therefore set forth representative concentrations (e.g., in percentages), concentration gradients and distribution profiles in the context of germanium, which may also be more generally applicable to other semiconductor species (e.g., from Group IV) that may be used for forming different types of compound semiconductor materials. Further, the base region 312 and the emitter region 320 are doped with dopants that may be configured to form a PN junction at or near the heterojunction. In the examples that are described below in the context of a p-n-p HBT using the Si/SiGe system, the dopant that is used to dope one or more of the base sub-layers 332, 334, 336, 338, 340 of the base region 312 comprises an n-type dopant, and more specifically, phosphorus, as noted previously. Other n-type dopants, such as As in a Si/SiGe system or other n-type dopants for other material systems, may be used to dope a heterojunction base region, such as, e.g., base region 312, in some additional and/or alternative arrangements. In other examples, a p-type dopant (e.g., having a conductivity type opposite from an n-type dopant) may be used in the context of an n-p-n HBT implementation to dope a heterojunction base region, such as, e.g., base region 312.

As will be set forth below, the concentration of germanium as a percentage may vary among the various base sub-layers 332, 334, 336, 338, 340. On the other hand, the collector region 306, the cap sub-layer 342, and the emitter region 320 are each comprised of silicon (e.g., devoid of a different semiconductor species such as germanium). In some examples, the second, third, fourth and fifth base sub-layers 334, 336, 338, 340 may each doped with carbon in approximately or substantially equal percentages, e.g., in a range of 0.15% to 0.3%. Carbon may be omitted in some examples, such as where a dopant other than phosphorus is implemented. In some examples, the SiGe compositions of the various base sub-layers 332, 334, 336, 338, 340 may comprise a range of ratios in the form of Si₁₋ₓGeₓ, where 0≤x≤1. Additional details with respect to particular SiGe ratios of different base sub-layers of a HBT heteroepitaxial structure such as, e.g., base sub-layers 332, 334, 336, 338, 340, may be found in U.S. Patent Application Publication No. 2023/0088544, which is incorporated by reference herein for all purposes.

With respect to optimizing the growth rates of different base sub-layers, and hence the time required to fabricate a base region of a particular overall thickness, while ensuring that the n-type dopant's distribution profile remains within a narrow width (e.g., having a steep or narrow peak), the inventors of the present disclosure have discovered that a combination flow involving different silicon precursors may be particularly advantageous in balancing various competing process constraints. Whereas using Si precursors such as DCS may generally provide better etch selectivity required for SEG/SAE processing over areas defined by patterned SiO₂/SiN layers, e.g., in an emitter window opening, DCS-based processing requires higher temperatures for supporting growth rates sufficient to sustain a cost-effective process flow for manufacturability. However, the higher temperatures used in DCS-based epitaxial processing can have a negative impact on the phosphorus distribution profile, resulting in wider peaks within the base region. Accordingly, examples herein provide a process flow where a DCS-based epitaxy process may be replaced during certain selective phases of the base region formation (e.g., the phases that include doping with n-type dopant species) by an epitaxy process based on another Si precursor such as silane (SiH₄) that affords sufficient growth rates at lower temperatures, thus without negatively impacting the dopant distribution profiles in the base region. To maintain the selectivity of the epitaxial processing, a co-etchant (e.g., hydrogen chloride (HCl)) may be used and/or adjusted accordingly during the selective phases according to some examples herein.

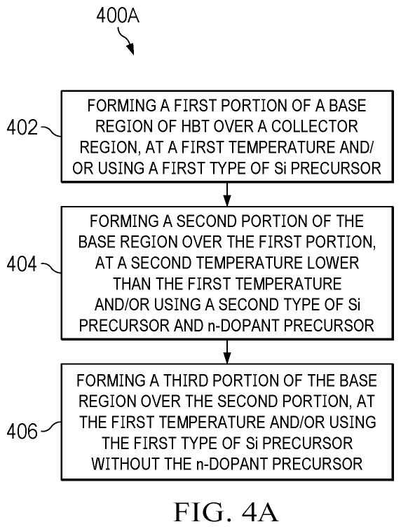

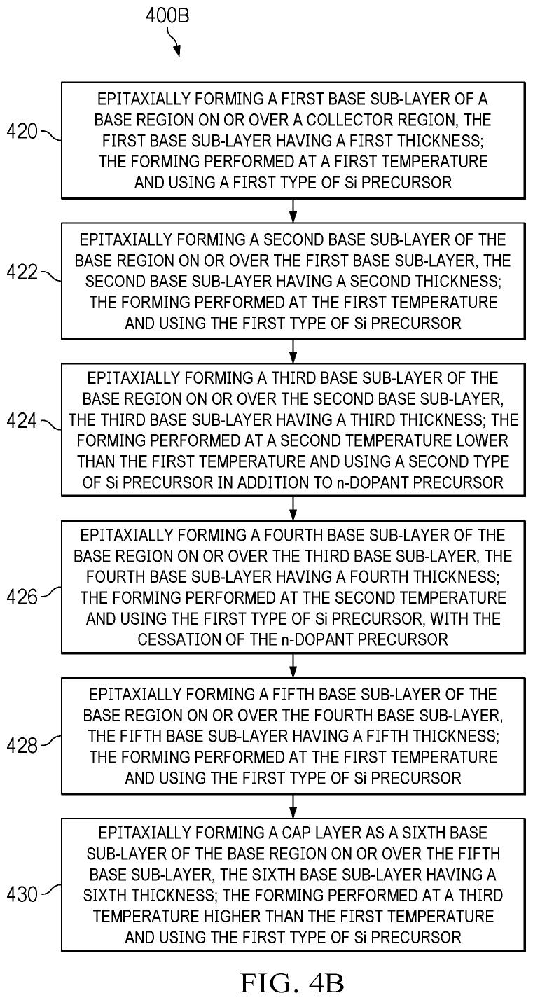

FIGS. 4A and 4B depict flowcharts of methods of IC fabrication where a base region of an HBT may be formed using a combinational flow of different Si precursors and process conditions with respect to different portions of the base region according to some examples. Example method 400A shown in FIG. 4A is representative of an overall process for forming a heterojunction base region having at least three portions that may be fabricated in successive stages in a suitable epitaxial flow (e.g., SEG/SAE) having respective process conditions. At block 402, a first portion of a base region of the HBT may be formed over a collector region, for example, at a first temperature and/or using a first type of Si precursor comprising DCS. As set forth previously, DCS may be used for providing better selectivity, while supporting a higher growth rate at elevated temperatures during the formation of the first base portion that does not involve doping with n-type species. At block 404, a second portion of the base region may be formed over the first base portion, at a second temperature lower than the first temperature and/or using a second type of Si precursor and a suitable n-dopant precursor. In some examples, the second type of Si precursor comprises silane and the n-type dopant precursor comprises phosphine (PH₃) that may be applied during the formation of at least a sub-portion of the second portion. As lower temperatures are utilized in the growth process involving the dopant, the dispersion of the dopant's distribution profile may be minimized, which may assist in confining the profile to a narrow width during subsequent fabrication phases. At block 406, a third portion of the base region may be formed over the second base portion, where a higher temperature may be applied and/or the supply of the first type of Si precursor may be resumed, while the n-dopant precursor supply is terminated. Accordingly, while the growth rates are not negatively impacted during the formation of the various base region portions, a temperature regime control is selectively applied to facilitate the confinement of the n-dopant's profile to a narrow area within the base region. Further, because a silane-based phase used for forming the second base portion may be advantageously modulated so as to achieve growth rates greater than the growth rates in some baseline techniques, the throughput of an HBT process flow may be advantageously improved in some examples herein. As will be seen further below, other processing conditions may also be suitably varied during the formation of the various base region portions, layer-by-layer, depending on the specific multilayer architecture of the base region. In particular, where a co-etchant is included to facilitate SEG/SAE processing, the flow rates of the co-etchant may also be suitably adjusted where silane is used.

Example method 400B of FIG. 4B is representative of a process for fabrication of a multilayered HBT's base region on a layer-by-layer basis, where a first subset of the layers may form a first base portion, a second subset of the layers may form a second base portion and a third subset of the layers may form a third base portion, which may correspond to the base portions described above. At block 420, a first base sub-layer of a base region may be epitaxially formed on or over a collector region, where the epitaxial processing may be performed at a first temperature using a first type of Si precursor (e.g., DCS) to generate the first base sub-layer having a first thickness. At block 422, a second base sub-layer of the base region may be epitaxially formed on or over the first base sub-layer, where the epitaxial processing is performed at the first temperature using the first type of Si precursor to generate the second base sub-layer having a second thickness. At block 424, a third base sub-layer of the base region may be epitaxially formed on or over the second base sub-layer, the third base sub-layer having a third thickness, where the epitaxial processing is performed at a second temperature lower than the first temperature using a second type of Si precursor (e.g., silane) in addition to supplying an n-dopant precursor (e.g., PH₃). At block 426, a fourth base sub-layer of the base region may be epitaxially formed on or over the third base sub-layer, the fourth base sub-layer having a fourth thickness, where the epitaxial processing is performed at the second temperature using the first type of Si precursor, while the supply of the n-dopant precursor is terminated. At block 428, a fifth base sub-layer of the base region may be epitaxially formed on or over the fourth base sub-layer, where the epitaxial processing is performed at the first temperature using the first type of Si precursor to generate the fifth base sub-layer having a fifth thickness. At block 430, a cap layer may be epitaxially formed on or over the fifth base sub-layer (e.g., as a sixth base sub-layer of the base region), the cap layer having a sixth thickness, where the epitaxial processing is performed at a third temperature higher than the first temperature and using the first type of Si precursor.

Depending on implementation, the epitaxial growth processes set forth above may comprise SEG/SAE processing in some examples. As described previously, epitaxial growth can be implemented using a variety of techniques, where appropriate process conditions, precursor gases (or other sources), carrier gases or other transport media, etc., may be used during the epitaxial growth to achieve target thicknesses of a particular HBT implementation such as, e.g., the sub-layers 332-342 and target concentrations of species in the sub-layers 332-342.

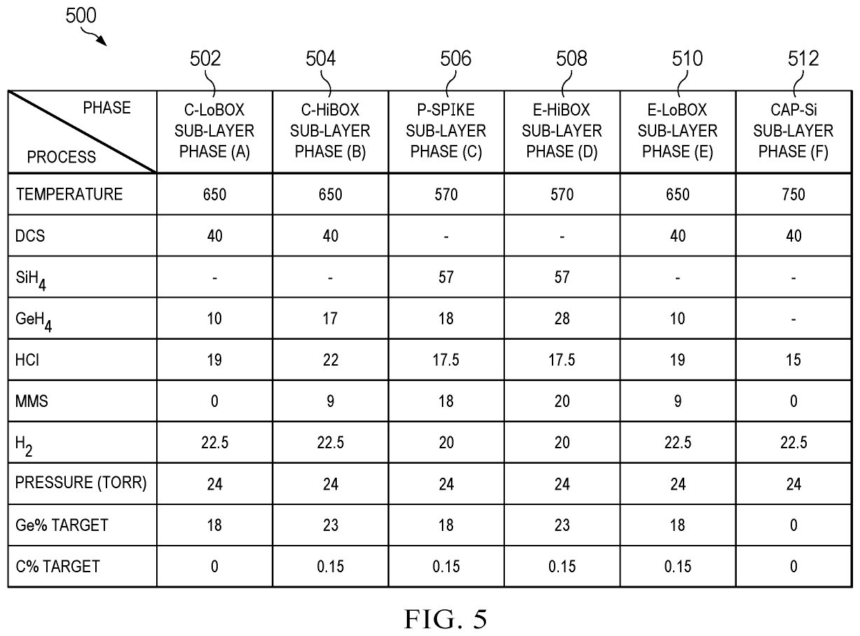

Continuing with the examples described above where the base sub-layers 332-340 are comprised of SiGe material, a SEG process for epitaxially growing the base sub-layers 332-340 may include a silicon-containing precursor gas, a germanium-containing precursor gas, and an etchant gas in some arrangements. Base sub-layer 342, comprising monocrystalline silicon, is devoid of germanium, as noted previously. FIG. 5 depicts a table 500 of various processing conditions for fabricating a layered base region as part of an HBT according to some examples. As illustrated, six columns 502-512 are set forth, each specifying a set of example process conditions, target thicknesses, time durations, etc., corresponding to the six base sub-layers 332-342, respectively, discussed hereinabove.

In some examples, a recipe for selectively growing the representative base sub-layers may include using DCS in some phases or stages at higher temperature regimes (e.g., around 650° C.) as the silicon-containing precursor gas (and possibly also as a co-etchant gas), which may be replaced with silane during certain other phases or stages involving lower temperature regimes (e.g., around 570° C.). A dopant-containing gas (e.g., an n-type dopant precursor gas) may be implemented during the epitaxial growth of a given layer to in-situ dope that layer. According to the examples herein, the n-type in-situ doping may be implemented during a silane-based growth phase rather than a DCS-based growth phase. Whereas both HCl and DCS may be implemented as co-etchants during the DCS-based phases, only HCl is implemented as an etchant during silane-based growth phases in order to maintain SEG/SAE processing. Further, because it is desirable to provide the n-type in-situ doped layer approximately centered within an HBT's base region, a silane-based phase and corresponding n-type in-situ doping may be implemented for the fabrication of a base sub-layer that is roughly in the middle of a given thickness of the base region, which may correspond to a preconfigured target depth from an emitter region (or, conversely, to a height from a collector region). Accordingly, in some examples, phosphine (PH₃) may be used as an n-type dopant precursor during the epitaxial growth of the third base sub-layer 336 to in-situ dope the third base sub-layer 336 with phosphorus, where the growth phase is based on silane implemented at temperatures less than the temperatures used for DCS-based growth phases. In some examples, a germanium-containing precursor (e.g., germane (GeH₄) may be applied at different rates during the fabrication of the base sub-layers 332-340. In some examples, a carbon-containing gas, such as mono-methylsilane (MMS) (CSiH₆), dimethylsilane (DMS) (C₂H₈Si), or trimethylsilane (TMS) (C₃H₁₀Si), may be used during the epitaxial growth of a selective subset of the base sub-layers, e.g., the second, third, fourth and fifth base sub-layers 334, 336, 338, 340, to in-situ dope the respective sub-layer with carbon.

In some examples, the base sub-layer 332 may be fabricated in a growth phase (Phase A) having processing conditions and target indicia as set forth in column 502 of the table 500. According to one implementation, Phase A may involve epitaxial growth by using DCS at flow rates of about 40 standard cubic centimeters per minute (sccm) in a temperature regime of about 650° C. and supplying germane precursor in a carrier gas (e.g., 6% germane in hydrogen (H₂)) at about 10 sccm, among other processing conditions, to achieve a target thickness of about 5 nm to 10 nm over a collector region.

In some examples, the base sub-layer 334 may be fabricated in a growth phase (Phase B) having processing conditions and target indicia as set forth in column 504 of the table 500. According to one implementation, Phase B may also involve epitaxial growth by using DCS at flow rates of about 40 sccm in a temperature regime of about 650° C., and supplying germane precursor (e.g., 6% germane in H₂) at about 17 sccm, among other processing conditions, to achieve a target thickness of about 15 nm to 25 nm over the base sub-layer 332.

In some examples, the base sub-layer 336 may be fabricated in a growth phase (Phase C) having processing conditions and target indicia as set forth in column 506 of the table 500. According to one implementation, Phase C may involve epitaxial growth by using silane at flow rates of about 57 sccm in a lower temperature regime of about 570° C. and supplying germane precursor (e.g., 6% germane in H₂) at about 18 sccm, along with phosphene in a carrier gas to achieve a desirable dopant concentration profile depending on application. In an example arrangement, Phase C may be implemented to achieve a narrow target thickness for the base sub-layer 336, e.g., about 2 nm to 10 nm, formed over the base sub-layer 334. According to examples herein, the base sub-layer 336 may be configured as a layer centered around a middle of the base region as set forth above in order to obtain a roughly normal (or, Gaussian) distribution of the dopant profile with a peak concentration within the third base sub-layer 336. In one arrangement, the n-doped base sub-layer 336 may be formed as a narrow band of about one-tenth thickness of the heteroepitaxial portion of the base region 312.

In some examples, the base sub-layer 338 may be fabricated in a growth phase (Phase D) having processing conditions and target indicia as set forth in column 508 of the table 500. According to one implementation, Phase D may involve epitaxial growth by using silane at flow rates of about 57 sccm in a lower temperature regime of about 570° C. and supplying germane precursor (e.g., 6% germane in H₂) at about 28 sccm, among other processing conditions, to achieve a target thickness of about 5 nm to 10 nm over the base sub-layer 336. According to examples herein, the supply of phosphene may be terminated in Phase D as well as subsequent growth phases.

In some examples, the base sub-layer 340 may be fabricated in a growth phase (Phase E) having processing conditions and target indicia as set forth in column 510 of the table 500. According to one implementation, Phase E may involve epitaxial growth by reverting to DCS at flow rates of about 40 sccm in a higher temperature regime of about 650° C. and supplying germane precursor (e.g., 6% germane in H₂) at about 10 sccm, among other processing conditions, to achieve a target thickness of about 5 nm to 15 nm over the base sub-layer 338.

In some examples, the base sub-layer 342 may be fabricated in a growth phase (Phase F) having processing conditions and target indicia as set forth in column 512 of the table 500. According to one implementation, Phase F may involve epitaxial growth using DCS at flow rates of about 40 sccm in a higher temperature regime of about 750° C., among other processing conditions. Because the base sub-layer 342 is operable as a cap layer of the base region interfacing with an emitter region, where the cap layer comprises an elemental Si material, the supply of germane may be terminated in Phase F processing. In some arrangements, the process conditions of Phase F may be adjusted so as to achieve a target thickness of about 20 nm to 50 nm over the base sub-layer 340 according to examples herein.

As set forth in the table 500 of FIG. 5, HCl may be used as an etchant or co-etchant throughout the epitaxial flow to facilitate the selectivity of the growth in a patterned region, e.g., such as an area over the collector region 306 defined for the fabrication of the heterojunction base region 312, whereas DCS is used as both a precursor and an etchant in the phases involving high temperature regimes. Using the combination of silane and HCl at a lower temperature regime instead of DCS and HCl at a higher temperature regime during Phase C provides a process condition mix that enables the in-situ doped dopant species to have a peak substantially confined near the mid-portion of the base region 312 while minimizing the potential broadening or widening of the peak during high temperature processing.

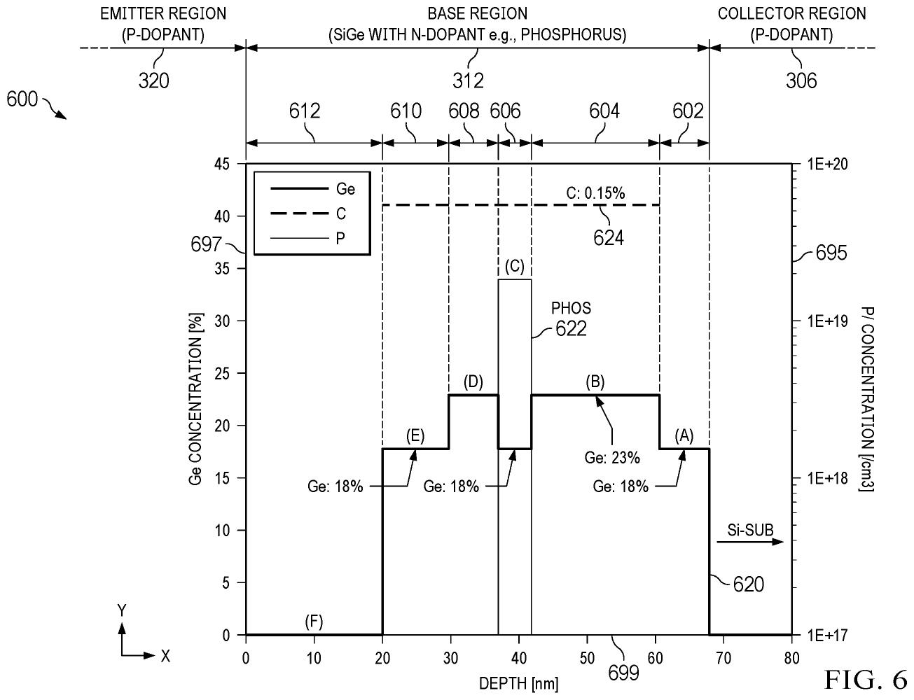

FIG. 6 is a chart 600 depicting approximate base epi target concentration gradients (e.g., before subsequent diffusion) of germanium, phosphorus and carbon in different growth phases for fabricating the base sub-layers 332-342, respectively, of the layered structure of FIG. 3 using the processing conditions of FIG. 5 according to some implementations. As illustrated, a depth continuum shown along an X-axis 699 may be demarcated into three regions, e.g., p-doped emitter region 320, n-doped base region 312 and p-doped collector region 306, where the p-doped collector region 306 is forms the deepest region of an HBT fabricated in or over the semiconductor substrate, e.g., the HBT shown in FIG. 1 or the HBT shown in FIG. 2 described in detail previously. It should be noted that the regional demarcations shown in FIG. 6 are not necessarily indicative of the actual p-n junction boundaries in the substrate as there would be diffusion of the dopant species within the substrate. The percentage concentration of germanium is shown along a first Y-axis 697 on a linear scale whereas the phosphorus concentration (atoms/cm³) is shown along a second Y-axis 695 on a logarithmic scale. Example thicknesses of the base sub-layers 332-342 are demarcated as depth segments 602-612, respectively, which may be obtained by the respective growth phases, Phases A-F, described above. In the chart 600, trace 620 is an example germanium concentration gradient and trace 622 is an example phosphorus concentration gradient. A trace 624 indicating a constant carbon concentration (in percentage) is also shown in the chart 600.

It should be noted that the concentration gradients of species shown in FIG. 6 are representative of target concentrations after deposition of the base sub-layers 332-342 and without significant additional processing (e.g., without any high temperature processing that would otherwise cause diffusion of the dopant species). The target germanium concentration gradient 620 increases from an interface between the first base sub-layer 332 and the collector region 306 to first a target concentration of about 18% in the first base sub-layer 332 (in Phase A processing) and then to a target concentration of about 23% in the second base sub-layer 334 (in Phase B processing). Thereafter, the target germanium concentration gradient 620 decreases to a lower concentration of about 18%, thereby creating a “trough” in the concentration profile in the third base sub-layer 336 in Phase C processing. From the trough concentration of about 18%, the target germanium concentration gradient 620 increases to a higher target concentration value (e.g., about 23%) in the fourth base sub-layer 338 (in Phase D processing), and then decreases to a lower concentration value (e.g., about 18%) in the fifth base sub-layer 340 (in Phase E processing). Thereafter, the target germanium concentration gradient 620 decreases to zero during the formation of the sixth base sub-layer 612 formed as a silicon cap layer in Phase F processing as noted above.

In some examples, the collector region 306 does not include germanium in a substantial amount prior to deposition of, e.g., the first base sub-layer 332, because the collector region 306 (already doped with a p-type dopant species) may not have been directly exposed to a germanium-containing precursor or material. It is contemplated that the collector region 306 may have trace or insubstantial amounts of germanium prior to deposition of the first base sub-layer 332 due to, e.g., indirect or insubstantial exposure to germanium. It is further contemplated that after deposition of the first base sub-layer 332, some amount of germanium may diffuse from the first base sub-layer 332 into the collector region 306 (due to Ge diffusion by thermal processing, for example).

The phosphorus concentration gradient 622 is targeted to have a peak in the third base sub-layer 336 formed in Phase C processing, which is expected to approximate a Gaussian distribution or a quasi-Gaussian distribution (e.g., having some skew) after processing and subsequent annealing. As shown, phosphorus doped in the third base sub-layer 336 is disposed between two interfaces where the germanium concentration in the third base sub-layer 336 is lower (e.g., having a trough concentration) relative to the concentration of germanium in the neighboring sub-layers, e.g., the second and fourth base sub-layers 334, 338. Further, it can be seen that the adjacent second and fourth base sub-layers 334 and 338 have the highest target concentrations of germanium. By having phosphorus disposed between the two interfaces or regions of increasing germanium concentration, whereby the phosphorous profile overlaps or is overlapped by the trough concentration of germanium, the effects of segregation diffusion may be better contained to within the base sub-layers 332-340 that form a heteroepitaxial structure for the base region 312 as described herein, which can help prevent a peak concentration of phosphorus from occurring or being repositioned outside of the base sub-layers 332-340.

In similar fashion, it can be seen that the carbon concentration gradient 624 overlaps the third base sub-layer 336 containing in-situ doped phosphorus. The presence of carbon can reduce phosphorus thermal diffusion mobility, such as during periods of thermal stress. Accordingly, by having a phosphorus-doped sub-layer overlapped and/or surrounded by sub-layers doped with carbon, the effects of diffusion, particularly when occurring during thermal stress, may be reduced so that more phosphorus remains within the third base sub-layer 336. It is therefore contemplated that carbon doping as described in examples herein may further help prevent a peak concentration of phosphorus from occurring or being repositioned outside of the base sub-layers 332-340.

After deposition of the sub-layers 332-342 of the base region 312, additional processing may be performed with respect to the remaining IC fabrication steps. For example, high temperature processing may be performed on the semiconductor wafer including an HBT formed according to examples herein. Specifically, in some implementations, an anneal process, such as a rapid thermal anneal (RTA), may be performed to activate dopants, e.g., of CMOS components and emitter diffusion drive-in. An example anneal process may include a nitrogen (N₂) spike RTA at a temperature of 1,080° C. spike for CMOS source/drain activation and emitter drive-in. Further, the base region 312 may undergo a number of thermal stresses after the formation of the base region 312 due to co-integration of other devices in a CBiCMOS design, which can cause further diffusion of species in the base region 312.

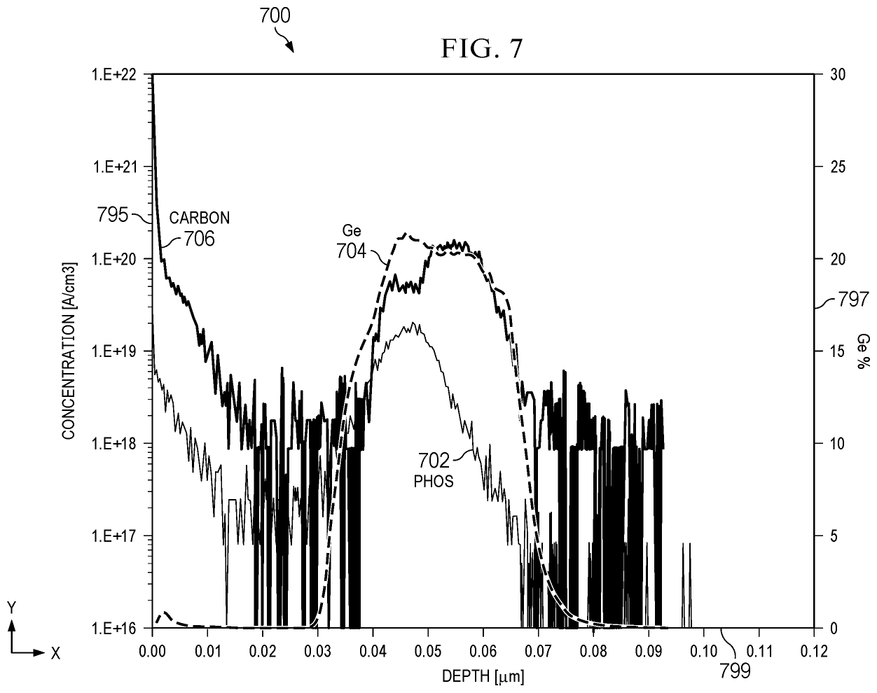

FIG. 7 is a chart 700 depicting dopant profiles in an HBT according to some examples. As illustrated, chart 700 is inclusive of three dynamic secondary ion mass spectrometry (DSIMS) traces representing a phosphorus concentration profile 702, a germanium concentration profile 704 and a carbon concentration profile 706, respectively, where the dopant profiles may include or exhibit diffusive effects and other artifacts. In some arrangements, an example chart 700 may be representative of as-grown dopant concentration profiles after forming the HBT's base region (e.g., before thermal processing is complete). Similar to the chart 600 described above, a depth continuum is shown along an X-axis 799, indicating a base region total thickness of about 70 nm to 80 nm. The percentage concentration of germanium is shown along a first Y-axis 797 on a linear scale whereas the phosphorus concentration (atoms/cm³) is shown along a second Y-axis 795 on a logarithmic scale. Whereas the DSIMS traces 702, 704, 706 in FIG. 7 may include signal noise as well as possible autodoping and/or indirect doping effects, etc., it can be seen that the example phosphorus concentration profile 702 evinces a substantially normal (Gaussian) distribution with a narrow peak centered around 45 nm to 47.5 nm within the base region. In some examples, the concentration of phosphorous peak may range from about 1×10¹⁹ atoms/cm³ to 5×10¹⁹ atoms/cm³, without limitation. In some examples, the peak concentrations may exhibit an order of magnitude range, e.g., about 5×10¹⁸ atoms/cm³ to 5×10¹⁹ atoms/cm³, depending on implementation.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A method of fabricating an integrated circuit (IC), comprising:
forming a first portion of a base region over a collector region of a heterojunction bipolar transistor (HBT), the first portion formed epitaxially at a first temperature;
forming a second portion of the base region over the first portion, the second portion formed epitaxially at a lower second temperature; and
forming a third portion of the base region over the second portion, the third portion formed epitaxially at the first temperature.

2. The method as recited in claim 1, further comprising using a first type of silicon precursor to form the first and third portions and using a different second type of silicon precursor to form the second portion.

3. The method as recited in claim 2, wherein the first type of silicon precursor comprises dichlorosilane (DCS, SiCl₂H₂) and the second type of silicon precursor comprises silane (SiH₄).

4. The method as recited in claim 1, further comprising applying hydrogen chloride (HCl) at a first flow rate while forming the second portion and at one or more second flow rates higher than the first flow rate while forming the first and third portions.

5. The method as recited in claim 1, further comprising applying phosphine (PH₃) as an n-type dopant precursor while forming a sub-portion of the second portion, the n-type dopant precursor for in-situ doping of the sub-portion at a peak concentration range of about 5×10¹⁸ atoms/cm³ to 5×10¹⁹ atoms/cm³.

6. The method as recited in claim 1, further comprising applying germane (GeH₄) as a germanium precursor while forming the first, second and third portions of the base region.

7. The method as recited in claim 1, wherein the third portion includes a compound semiconductor, and further comprising:
forming a cap sub-layer of the base region over the third portion, the cap sub-layer including an elemental semiconductor; and
forming an emitter region over the cap sub-layer.

8. The method as recited in claim 1, further comprising doping the third portion, the second portion and a sub-portion of the first portion immediately underlying the second portion, each with carbon at substantially equal concentrations.

9. An integrated circuit (IC), comprising:
a semiconductor substrate; and
a heterojunction bipolar transistor comprising a collector region, a base region and an emitter region, the collector region formed in or over the semiconductor substrate, the base region disposed between the collector region and the emitter region, the base region comprising a heteroepitaxial portion including a narrow band of an n-dopant region, the narrow band is of about one-tenth thickness of the heteroepitaxial portion.

10. The IC as recited in claim 9, wherein the heteroepitaxial portion comprises silicon-germanium (SiGe) and the n-dopant region is doped with phosphorus at a peak concentration range of about 5×10¹⁸ atoms/cm³ to 5×10¹⁹ atoms/cm³.

11. The IC as recited in claim 9, wherein the narrow band overlaps a trough of a germanium distribution profile in the heteroepitaxial portion.

12. The IC as recited in claim 9, wherein the base region further comprises a cap sub-layer overlying the heteroepitaxial portion and beneath the emitter region, the cap sub-layer including an elemental semiconductor.

13. The IC as recited in claim 12, wherein the cap sub-layer has a thickness of about 30 nanometers (nm).

14. The IC as recited in claim 9, wherein the narrow band is about 5 nm thick.

15. A method of fabricating an integrated circuit (IC), comprising:
forming a first portion of a base region over a collector region of a heterojunction bipolar transistor (HBT), the second portion formed epitaxially using a first type of silicon precursor;
forming a second portion of the base region over the first portion, the second portion formed epitaxially using a different second type of silicon precursor; and
forming a third portion of the base region over the second portion, the third portion formed epitaxially using the first type of silicon precursor.

16. The method as recited in claim 15, wherein the first and third portions are formed at a first temperature and the second portion is formed at a lower second temperature.

17. The method as recited in claim 15, wherein the first type of silicon precursor comprises dichlorosilane (DCS, SiCl₂H₂) and the second type of silicon precursor comprises silane (SiH₄).

18. The method as recited in claim 15, further comprising applying hydrogen chloride (HCl) at a first flow rate while forming the second portion and at one or more second flow rates higher than the first flow rate while forming the first and third portions.

19. The method as recited in claim 15, further comprising applying phosphine (PH₃) as an n-type dopant precursor while forming a sub-portion of the second portion, the n-type dopant precursor for in-situ doping of the sub-portion at a peak concentration range of about 5×10¹⁸ atoms/cm³ to 5×10¹⁹ atoms/cm³.

20. The method as recited in claim 15, further comprising applying germane (GeH₄) as a germanium precursor while forming the first, second and third portions of the base region.
